(19) United States
(12) Patent Application Publication
(10) Pub. No.: US 2026/0371952 A1
(43) Pub. Date: Nov. 19, 2026

(54) PATTERNING LAYER FOR FORMING CONTACT ISOLATION STRUCTURES IN SEMICONDUCTOR DEVICES

(71) Applicant: Taiwan Semiconductor Manufacturing Company, Ltd., Hsinchu (TW)

(72) Inventor: Guan-Yao TU, Hsinchu City (TW)

(73) Assignee: Taiwan Semiconductor Manufacturing Company, Ltd., Hsinchu (TW)

(21) Appl. No.: 19/210,858

(22) Filed: May 16, 2025

(51) Int. Cl. H10P 14/60; H10D 30/00; H10D 30/01; H10D 30/43; H10D 30/67; H10D 62/10; H10P 50/28

(52) U.S. Cl. CPC H10P 14/6336; H10D 30/014; H10D 30/0191; H10D 30/43; H10D 30/502; H10D 30/6735; H10D 62/121; H10P 50/283

(57) ABSTRACT

The present disclosure describes a method of forming a carbon-based patterning layer for forming isolation structures between adjacent source/drain contact structures of a field-effect-transistors (FETs). The disclosed method forms a carbon-based patterning layer with a high Young's modulus capable of reducing patterning wiggling during etching operations, to prevent critical dimension (CD) non-uniformity in the isolation structures.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). As dimensions of semiconductor devices shrink, the size of FETs and other components becomes smaller. Variations in critical dimensions can significantly affect yield and reliability of these devices.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIGS. 1B and 1C illustrate cross-sectional views of a semiconductor device with nanostructured channel layers and source/drain contact structures, in accordance with some embodiments.

FIG. 1D illustrates a cross-sectional view of isolation structures of a semiconductor device, in accordance with some embodiments.

FIG. 2 is a flow diagram of a method for fabricating a semiconductor device with nanostructured channel layers and source/drain contact structures, in accordance with some embodiments.

FIGS. 3A-11A and 3B-11B illustrate different cross-sectional views of a semiconductor device with nanostructured channel layers and source/drain contact structures at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not dictate a relationship between the embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5%, ±10%, ±10-15%, ±15~20% of the value). These values are merely examples and are not intended to be limiting. The terms “about” and “substantially” can refer to a percentage of the values as interpreted by those skilled in relevant art(s) in light of the teachings herein.

The gate-all-around (GAA) transistor structures disclosed herein may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

A substrate with multiple gate-all-around field effect transistors (GAA FET) includes (a) source/drain (S/D) regions formed on either side of a gate structure of the GAA FET, and (b) S/D regions of adjacent GAA FETs formed on adjacent fin structures. S/D contact structures of GAA FETs formed on adjacent fin structures can be separated by an isolation structure. A width of this isolation structure is a critical dimension (CD) because a CD too large can affect current flow and a CD too small can lead to unintended coupling, causing cross-talk between adjacent S/D regions. The present disclosure is related to a semiconductor device and a method of forming the semiconductor device that includes a cut metal drain (CMD) process. The CMD process disclosed herein is directed to reducing position and dimensional irregularities in CDs of isolation structures separating adjacent source/drain contact structures. A CMD process refers to a fabrication process, where dielectric layers and etch stop layers (ESLs) overlying the S/D regions are etched to form S/D contact openings. The S/D contact openings are subsequently filled with a metal contact layer to form S/D contact structures.

The CD of the isolation structure can suffer from uniformity degradation due to patterning and etching limitations. Masking material limitations, misalignment, and irregularities during patterning and etching can cause CD-related defects, which can lead to undesirable variations in device performance. For example, forming the isolation structure includes depositing and patterning hard mask layers. Hard mask layers formed of a soft material (e.g., a material with low Young's modulus) can cause position and dimensional irregularities in the pattern (also referred to as “pattern wiggling”) that can be transferred to the isolation structure. Pattern wiggling or patterning irregularities can result in a missing isolation structure or an isolation structure with a small width during subsequent processing operations.

To address the aforementioned challenges, the present disclosure provides a method of depositing a patterning layer with a high Young's modulus. The patterning layer disclosed herein, owing to its high Young's modulus, can (a) withstand the stress of multiple etching cycles without undergoing degradation, (b) reduce line bending (form a masking layer with substantially vertical sidewalls) issues during patterning and etching operations to maintain positional and dimensional accuracy of device features, and (c) provide etch selectivity for effectively protecting underlying layers during etching operations.

The disclosed method of forming the patterning layer can also help deposit a non-conformal patterning layer within openings and/or trenches formed during formation of the isolation structures. The non-conformal layer is evenly deposited over flat surface areas as well as areas with deep features (e.g., deep trenches and narrow openings). The patterning layer has a substantially planarized top surface irrespective of the features on an underlying layer.

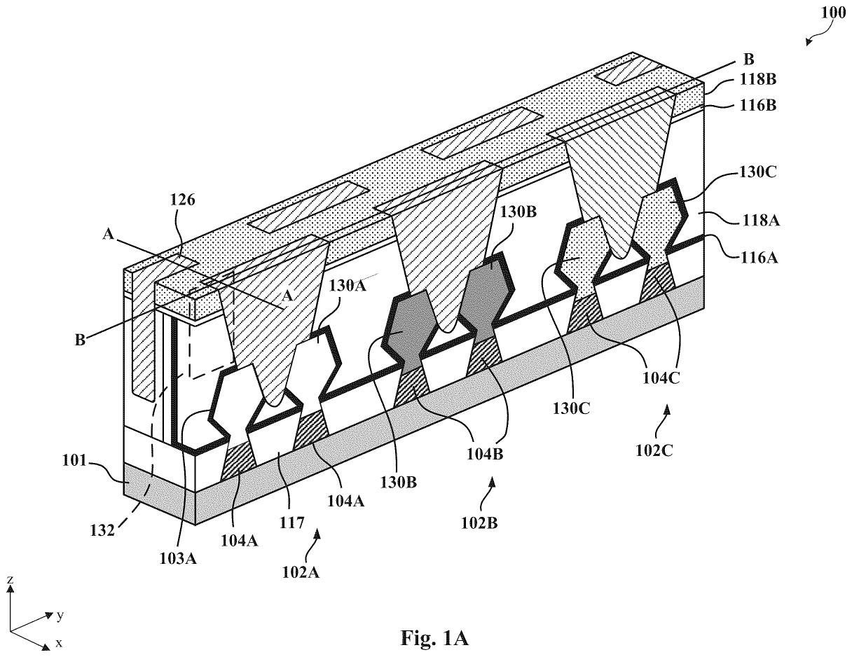

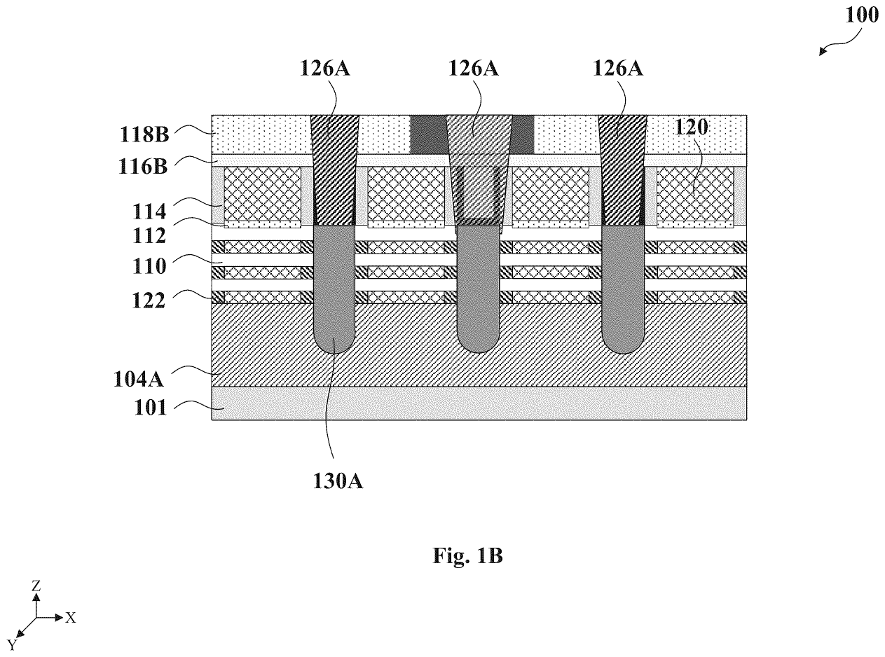

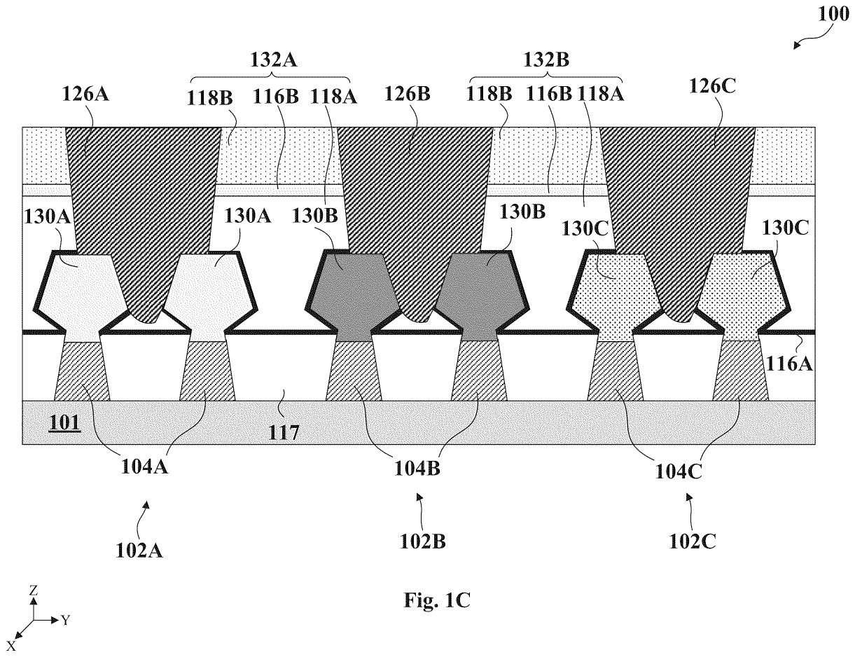

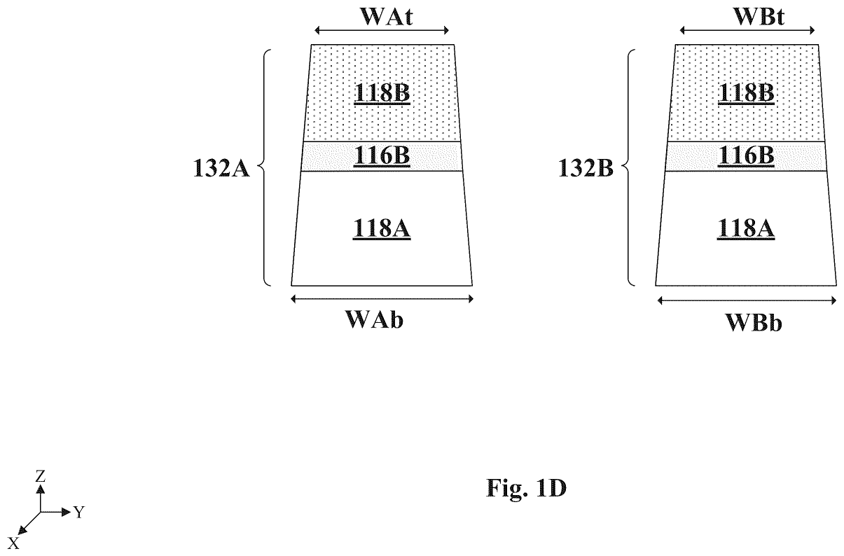

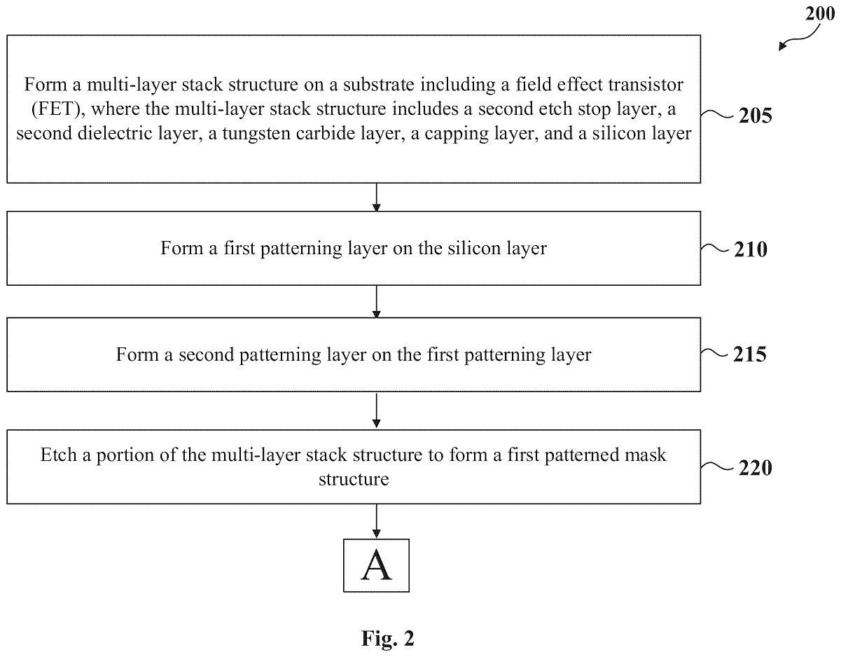

A semiconductor device 100 with FETs 102A, 102B, and 102C is described with reference to FIGS. 1A-1C, according to some embodiments. In some embodiments, FETs 102A, 102B, and 102C can represent GAA FETs. In some embodiments, FETs 102A, 102B and 102C can represent n-type finFETs 102A, 102B, and 102C (NFETs 102A, 102B, and 102C) or p-type finFETs 102A, 102B, and 102C (PFETs 102A, 102B, and 102C), or any combination thereof. The discussion of FETs 102A, 102B, and 102C applies to both NFET and PFET, unless mentioned otherwise. Though three FETs are discussed with reference to FIGS. 1A-1C, semiconductor device 100 can have any number of FETs. FIG. 1A illustrates an isometric view of semiconductor device 100, according to some embodiments. Semiconductor device 100 can have different cross-sectional views along lines A-A and B-B of FIG. 1A, according to some embodiments. Line A-A can extend along the x-axis and line B-B can extend along the y-axis.

Referring to FIGS. 1A and 1C, in some embodiments, FETs 102A, 102B, and 102C can include an array of fin structures 104A, 104B, and 104C respectively, disposed on substrate 101. Fin structures 104A, 104B, and 104C can also be referred to as “sheet bases,” “fin bases,” or “protrusions” which can extend along an x-axis. Base structures 104A, 104B, and 104C can be separated by shallow trench isolation (STI) regions 117. Although the arrays for FETs 102A, 102B and 102C have been shown to include two fin structures each, the arrays can include more than two fin structures.

Referring to FIGS. 1B and 1C, in some embodiments, FET 102A can further include (i) a stack of nanostructured channel layers (also referred to herein as “nanostructured layers 110” or “nanostructured channel regions 110”) disposed on base structure 104A, (ii) GAA structure 120 (also referred to herein as “gate structure 120”) disposed on and around nanostructured channel layers 110, (iii) outer gate spacers 114 disposed along sidewalls of gate structure 120, (iv) an array of S/D regions 130A (also referred to herein as “heavily-doped S/D regions 130A”) disposed in portions of fin structures 104A that are not covered by gate structure 120, and (v) S/D contact structure 126A disposed on S/D regions 130A. Referring to FIG. 1C, in some embodiments, FET 102B can further include (i) a stack of nanostructured channel layers (also referred to herein as “nanostructured layers 110” or “nanostructured channel regions 110”) disposed on base structure 104B, (ii) GAA structure 120 (also referred to herein as “gate structure 120”) disposed on and around nanostructured channel layers 110, (iii) outer gate spacers 114 disposed along sidewalls of gate structure 120, (iv) an array of S/D regions 130B (also referred to herein as “heavily-doped S/D regions 130B”) disposed in portions of fin structures 104B that are not covered by gate structure 120, and (v) S/D contact structure 126B disposed on S/D regions 130B. Referring to FIG. 1C, in some embodiments, FET 102C can further include (i) a stack of nanostructured channel layers (also referred herein to as “nanostructured layers 110” or “nanostructured channel regions 110”) disposed on base structure 104A, (ii) GAA structure 120 (also referred to herein as “gate structure 120”) disposed on and around nanostructured channel layers 110, (iii) outer gate spacers 114 disposed along sidewalls of gate structure 120, (iv) an array of S/D regions 130C (also referred to herein as “heavily-doped S/D regions 130C”) disposed in portions of fin structures 104C that are not covered by gate structure 120, and (v) S/D contact structure 126C disposed on S/D regions 130C. In some embodiments, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel layers 110 can be in the form of nanosheets, nanowires, nanorods, nanotubes, or other suitable nanostructured shapes.

FETs 102A, 102B, and 102C can further include (i) first ESL 116A to protect gate structure 120 and S/D regions 130A, 130B, and 130C, (ii) first dielectric layer 118A disposed on top of first ESL 116A, (iii) second ESL 116B disposed on first dielectric layer 118A, and (iv) second dielectric layer 118B formed on second ESL 116B.

S/D contact structures 126A and 126B are separated by isolation structure 132A. S/D contact structures 126B and 126C are separated by isolation structure 132B, as shown in FIG. 1C. According to some embodiments, isolation structures 132A an 132B can include first dielectric layer 118A, second etch stop layer 116B, and second dielectric layer 118B. According to some embodiments, isolation structures 132A and 132B can have a tapered shape. As shown in FIG. 1D, according to some embodiments, isolation structure 132A can have a top portion with width WAt and a bottom portion with width WAb, where WAb is greater than WAt. Isolation structure 132B can have a top portion with width WBt and a bottom portion with width WBb, where WBb is greater than WBt. The ratio of width WAt to width WAb can be, for example, between about 0.8 and about 0.9. The ratio of width WBt to width WBb can be, for example, between about 0.85 and about 0.95. In some embodiments, since widths WAt, Wbt, WAb, and WBb control device performance, they are critical dimensions of isolation structures 132A and 132B. According to some embodiments, a difference between WAt and WBt can be between about A and about B. According to some embodiments, a difference between WAb and WBb can be between about 0.05 and about 0.1.

According to some embodiments, FIG. 1B illustrates a cross sectional view of FET 102A along line A-A of FIG. 1A, and shows a portion of semiconductor device 100. According to some embodiments, FIG. 1C illustrates a cross-sectional view of FETs 102A and 102B along line B-B of FIG. 1A. FIGS. 1B and 1C illustrate cross-sectional views of FETs 102A and 102B with additional elements that are not shown in FIG. 1A for simplicity. The discussion of FET 102A applies to FETs 102B and 102C, unless mentioned otherwise. The discussion of elements in FIGS. 1A-1C with the same annotations applies to each other, unless mentioned otherwise.

Referring to FIGS. 1A-1C, semiconductor device 100 can be formed on substrate 101. Substrate 101 can be a semiconductor material, such as silicon, germanium (Ge), silicon germanium (SiGe), a silicon-on-insulator (SOI) structure, and a combination thereof. Further, substrate 101 can be doped with p-type dopants (e.g., boron, indium, aluminum, or gallium) or n-type dopants (e.g., phosphorus or arsenic).

Referring to FIGS. 1B and 1C, S/D regions 130A, 130B, and 130C can be grown on base structures 104A, 104B, and 104C, respectively, and can include epitaxially-grown semiconductor materials. In some embodiments, the epitaxially-grown semiconductor material can include the same material or a different material from the material of substrate 101. S/D regions 130A, 130B, and 130C can be n- or p-type. In some embodiments, the term “p-type” defines a structure, layer, and/or region doped with p-type dopants, such as boron, and the term “n-type” defines a structure, layer, and/or region doped with n-type dopants, such as phosphorus. In some embodiments, S/D regions 130A, 130B, and 130C can include SiAs, SiC, SiCP, SiGe, SiGeB, GeB, SiGeSnB, a III-V semiconductor compound, any other suitable semiconductor material, or a combination thereof.

In some embodiments, S/D contact structures 126A, 126B, and 126C on S/D regions 130A, 130B, and 130C, respectively, can include (i) a silicide layer (not shown), (ii) a liner (not shown), and (iii) a S/D metal contact layer disposed on silicide layer (not shown). In some embodiments, the silicide layer can include nickel silicide (NiSi), tungsten silicide (WSi₂), titanium silicide (TiSi₂), cobalt silicide (CoSi₂), or other suitable metal silicides. In some embodiments, S/D metal contact layer can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), any other suitable conductive material, and a combination thereof. In some embodiments, the liner can include a nitride material, such as titanium nitride (TiN) and tantalum nitride (TaN).

Gate structure 120 can be a multi-layer structure and can surround nanostructured channel layers 110, as shown in FIG. 1B. Gate structure 120 can be referred to as a “gate-all-around (GAA) structure.” A first portion of gate structure 120 disposed on the nanostructured channel layers 110 can be electrically isolated from adjacent S/D regions by outer gate spacers 114. A second portion of gate structure 120 surrounding nanostructured channel layers 110 can be electrically isolated from adjacent S/D regions by inner gate spacers 122. Inner gate spacers 122 and outer gate spacers 114 can include an insulating material, such as SiO₂, SiN, SiCN, SiOCN, and any other suitable insulating material.

Gate structure 120 can include (i) an interfacial oxide layer (IL) 112, (ii) a high-k (HK) gate dielectric layer, (iii) a work function metal (WFM) layer, and (iv) a gate metal fill layer. FIG. 1B shows that the layers of GAA structure 120 are wrapped around nanostructured channel layers 110.

IL layers 112 can be disposed on nanostructured channel layers 110. In some embodiments, IL layers 112 can include SiO₂, silicon germanium oxide (SiGeOₓ), germanium oxide (GeOₓ), or other suitable oxide materials. HK gate dielectric layers can be disposed on IL layers 112 and can include (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. The term “high-k” refers to a high dielectric constant. In the field of semiconductor device structures and manufacturing processes, high-k can refer to a dielectric constant that is greater than the dielectric constant of SiO₂ (e.g., greater than 3.9).

WFM layer can be n- or p-type for n-or p-type FET 102A, respectively. In some embodiments, n-type WFM layer can include a metallic material with a work function value closer to a conduction band energy than a valence band energy of a material of nanostructured channel layers 110. For example, an n-type WFM layer can include an Al-based or Al-doped metallic material with a work function value less than about 4.5 eV (e.g., about 3.5 eV to about 4.4 eV), which can be closer to the conduction band energy (e.g., 4.1 eV for Si or 3.8 eV for SiGe) than the valence band energy (e.g., 5.2 eV for Si or 4.8 eV for SiGe) of Si-based or SiGe-based nanostructured channel layers 110. In some embodiments, the n-type WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, other suitable Al-based materials, or a combination thereof.

In some embodiments, a p-type WFM layer can include a metallic material with a work function value closer to a valence band-edge energy than a conduction band-edge energy of a material of nanostructured channel layers 110. For example, the p-type WFM layer can include a substantially Al-free (e.g., with no Al) metallic material with a work function value equal to or greater than 4.5 eV (e.g., about 4.5 eV to about 5.5 eV), which can be closer to the valence band-edge energy (e.g., 5.2 eV for Si or 4.8 eV for SiGe) than the conduction band-edge energy (e.g., 4.1 eV for Si or 3.8 eV for SiGe) of Si-based or SiGe-based nanostructured channel layers 110. In some embodiments, the p-type WFM layer can include substantially Al-free (e.g., with no Al): (i) Ti-based nitrides or alloys, such as TiN, TiSiN, titanium gold (Ti—Au) alloy, titanium copper (Ti—Cu) alloy, titanium chromium (Ti—Cr) alloy, titanium cobalt (Ti—Co) alloy, titanium molybdenum (Ti—Mo) alloy, and titanium nickel (Ti—Ni) alloy; (ii) Ta-based nitrides or alloys, such as TaN, TaSiN, Ta—Au alloy, Ta—Cu alloy, Ta—W alloy, tantalum platinum (Ta—Pt) alloy, Ta—Mo alloy, Ta—Ti alloy, and Ta—Ni alloy; (iv) metal nitrides, such as molybdenum nitride (MoN) and tungsten nitride (WN); (iii) other suitable Al-free metallic materials; (iv) and combinations thereof. In some embodiments, the WFM layer can include a thickness ranging from about 1 nm to about 4 nm.

In some embodiments, a gate metal fill layer can include a suitable conductive material, such as tungsten (W), titanium (Ti), silver (Ag), ruthenium (Ru), molybdenum (Mo), copper (Cu), cobalt (Co), aluminum (Al), iridium (Ir), nickel (Ni), any other suitable conductive material, and a combination thereof. In some embodiments, the gate metal fill layer can include a substantially fluorine-free metal layer (e.g., fluorine-free W). The substantially fluorine-free metal layer can include an amount of fluorine contaminants less than about 5 atomic percent in the form of ions, atoms, and/or molecules.

In some embodiments, STI regions 117, first and second ESLs 116A and 116B, and first and second dielectric layers 118A and 118B can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), silicon germanium oxide (SiGeOₓ), and any other suitable insulating material.

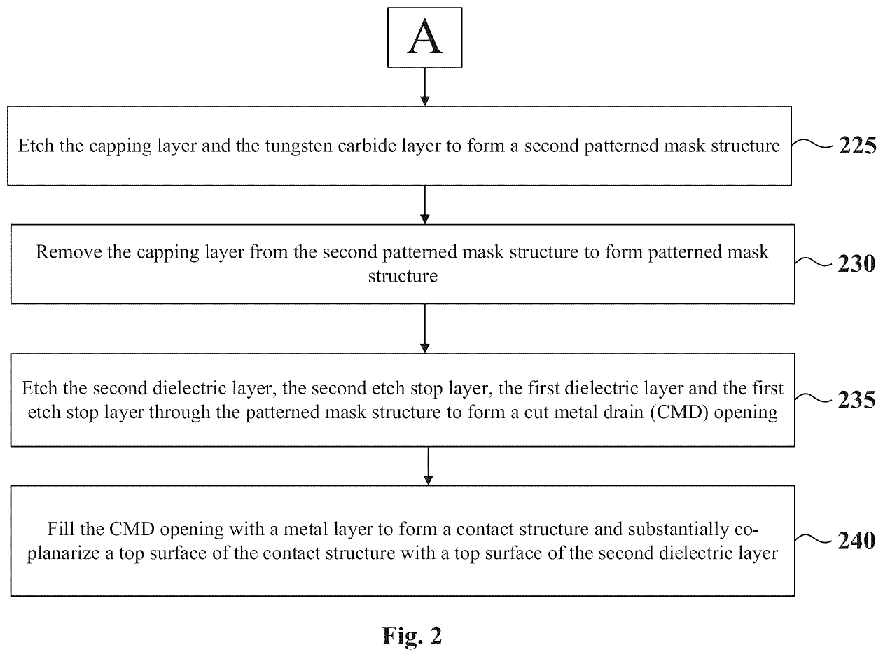

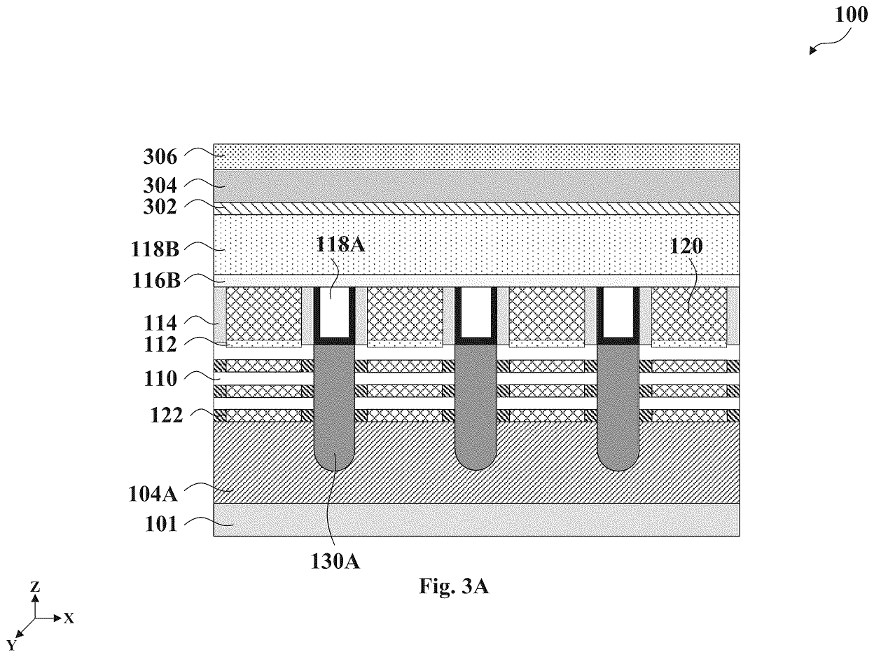

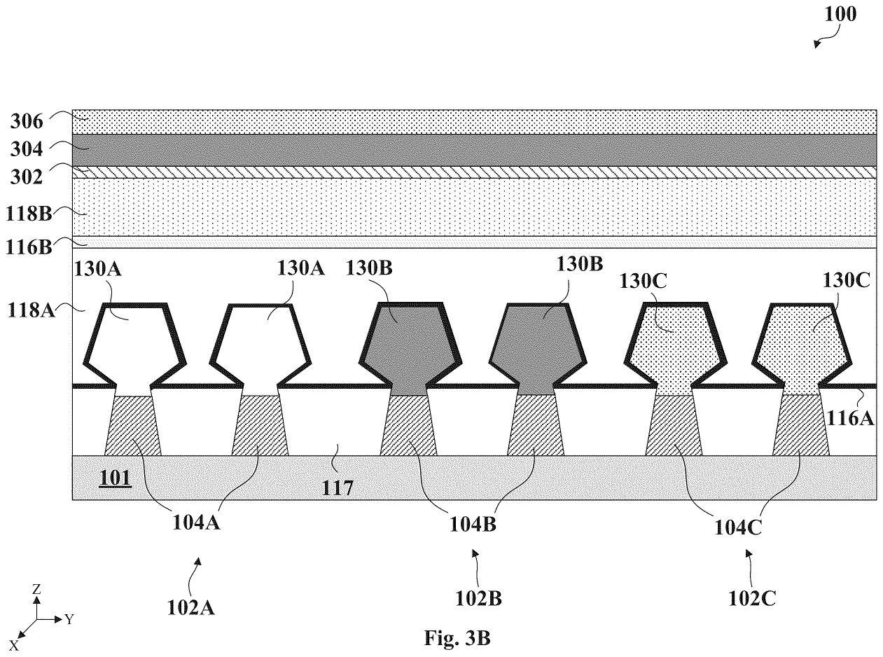

FIG. 2 is a flow diagram of an example method 200 for fabricating semiconductor device 100 as shown in FIGS. 1A-1C, according to some embodiments. For illustrative purposes, the operations illustrated in FIG. 2 will be described with reference to the example fabrication process for fabricating semiconductor device 100 as illustrated in FIGS. 3A-11A and 3B-11B are cross-sectional views of semiconductor device 100 along line A-A of FIG. 1A at various stages of fabrication, according to some embodiments. FIGS. 3B-11B are cross-sectional views of semiconductor device 100 along line B-B of FIG. 1A at various stages of fabrication, according to some embodiments. Operations can be performed in a different order or not performed depending on specific applications. It should be noted that method 200 may not produce a complete semiconductor device 100. Accordingly, it is understood that additional operations can be provided before, during, and after method 200, and that some other operation may only be briefly described herein. Elements in FIGS. 3A-11A and 3B-11B with the same annotations as elements in FIGS. 1A-1D are described above.

The method 200 begins at operation 205 by forming a multi-layer stack structure on a substrate, where the substrate includes a FET. For example, as shown in FIGS. 3A and 3B, substrate 101 with FETs 102A, 102B, and 102C is provided. FETs 102A, 102B, and 102C can be, for example, GAA FETs, as shown in FIGS. 3A and 3B. A multi-layer stack structure can be formed on FETs 102A, 102B, and 102C. Forming the multi-layer stack structure can include sequential operations of (i) depositing second ESL 116B on first dielectric layer 118A, (ii) depositing second dielectric layer 118B, (iii) depositing tungsten carbide (WC) layer 302, (iv) depositing capping layer 304, and (v) depositing silicon layer 306. In some embodiments, capping layer 304 can include a silicon oxide layer with a thickness between about 35 nm and about 43 nm. The thickness of WC layer 302 can be, for example, between about 11 nm and about 17 nm.

In some embodiments, WC layer 302 can have a Young's modulus between about 190 GPa and about 200 GPa. For example, WC layer 302 can have a Young's modulus of about 197 GPa. Due to its hardness, in subsequent processing operations, WC layer 302 can be used as a hard mask layer for etching underlying layers in the multi-layer stack structure. The high Young's modulus of WC layer 302 can reduce pattern weakness. Additionally, it can mitigate pattern weakness transferred from first patterning layer 402 and second patterning layer 502. In some embodiments WC layer 302 can be deposited by a plasma-enhanced chemical vapor deposition (PECVD) process. In some embodiments, the PECVD process for WC layer deposition can be performed by co-flowing tungsten fluoride (WF₃) and methane (CH₄) at a temperature between about 300 °C and about 400 °C.

As an alternative to WC, in some embodiments a tungsten (W) layer can be used, implying that a W layer can be used in place of WC layer 302. In some embodiments, W layer can be deposited by PECVD process by co-flowing tungsten hexafluoride (WF₆) and H₂. In some embodiments, W can be deposited by PECVD by co-flowing WCl₅ and H₂. In some embodiments, W layer can be deposited by sputtering.

In some embodiments, capping layer 304 can be used as a hard mask layer in subsequent processing operations. Capping layer 304 can be formed of one or more of silicon oxide (SiO₂) and silicon oxycarbonitride (SiOCN). Capping layer 304 formed of, for example, SiO₂ and can have a Young's modulus between about 60 GPa and about 70 GPa (e.g., about 66 GPa).

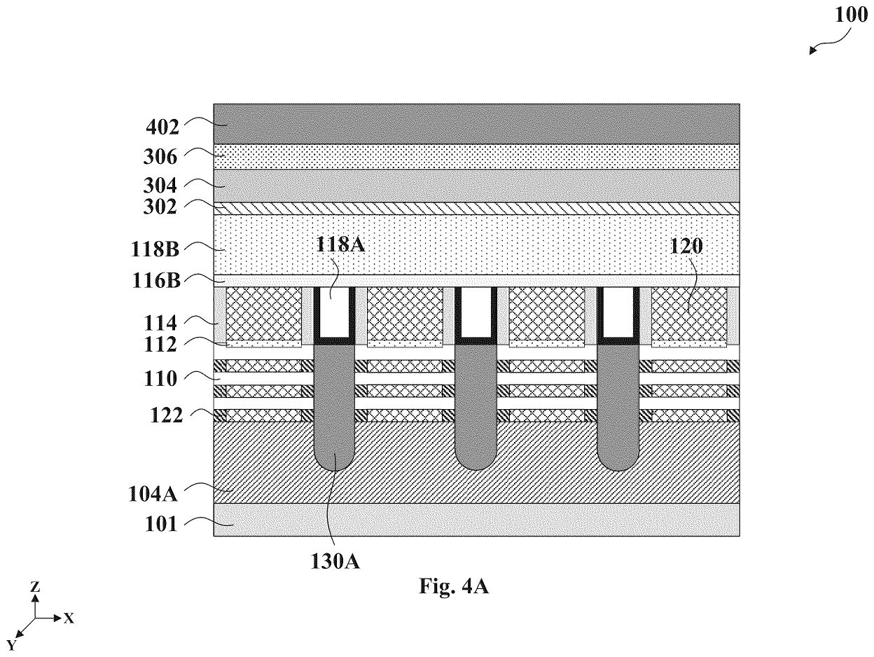

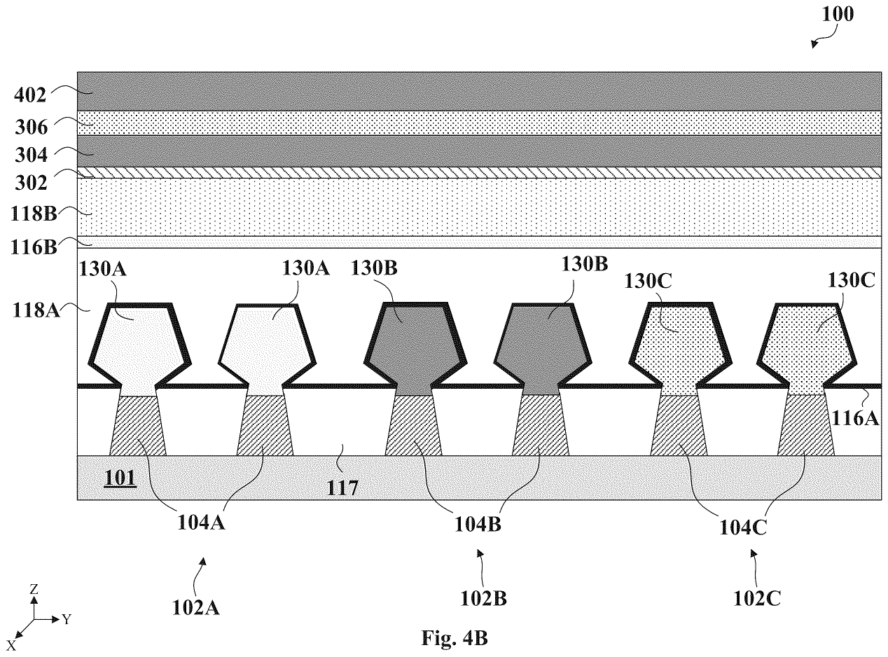

Referring to FIG. 2, in operation 210, a first patterning layer is formed on the silicon layer. In some embodiments, first patterning layer 402 can be deposited on silicon layer 306, as shown in FIGS. 4A and 4B. According to some embodiments, first patterning layer 402 can be a carbon-based layer. First patterning layer 402 can be, for example, an amorphous carbon layer. The amorphous carbon layer can also be referred to as “a-C layer.” The present disclosure provides a method of depositing an a-C carbon layer with a high Young's modulus. According to some embodiments, the high Young's modulus a-C layer can be deposited by PECVD. The deposited films can have a Young's modulus between about 20 GPa to about 200 GPa.

In some embodiments, the a-C layer can be deposited by PECVD by flowing a processing gas at a temperature between about 350 °C and about 450 °C. PECVD can be performed at a temperature of, for example, about 400 °C. In some embodiments, the processing gas can include acetylene (C₂H₂) and H₂. PECVD can be performed at a temperature of, for example, about 400 °C. In some embodiments, argon (Ar) can be co-flowed with the processing gas during the PECVD process at a flow rate between about 14000 sccm and about 17000 sccm. The Ar can be flowed at a rate of, for example, 16000 sccm. Chamber pressure can play a critical role during deposition of a-C layer by PECVD. Variations in chamber pressure can form a-C layers with different levels of hardness, which is reflected by the Young's modulus of the deposited layer. In some embodiments, the PECVD process can be performed at a pressure between about 9 torr and about 18 torr to form an a-C layer with a Young's modulus between about 20 GPa and about 80 GPa. In some embodiments, the PECVD process can be performed at a pressure between about 1 torr and about 8 torr to form an a-C layer with a Young's modulus between about 80 GPa and about 120 GPa. In some embodiments, the PECVD process can be performed at a pressure between about 1 torr and about 8 torr, using a low frequency power supply between about 800 W and about 4000 W, to form an a-C layer with a Young's modulus between about 120 GPa and about 200 GPa. The high Young's modulus of the a-C layer helps reduce pattern wiggling or line wiggling during etching of first patterning layer 402.

In some embodiments, the a-C layer which forms first patterning layer 402 can have a thickness between about 40 nm and about 53 nm. In some embodiments, first patterning layer 402 can have a density between about 1.2 gm/cm³ and about 1.5 gm/cm³.

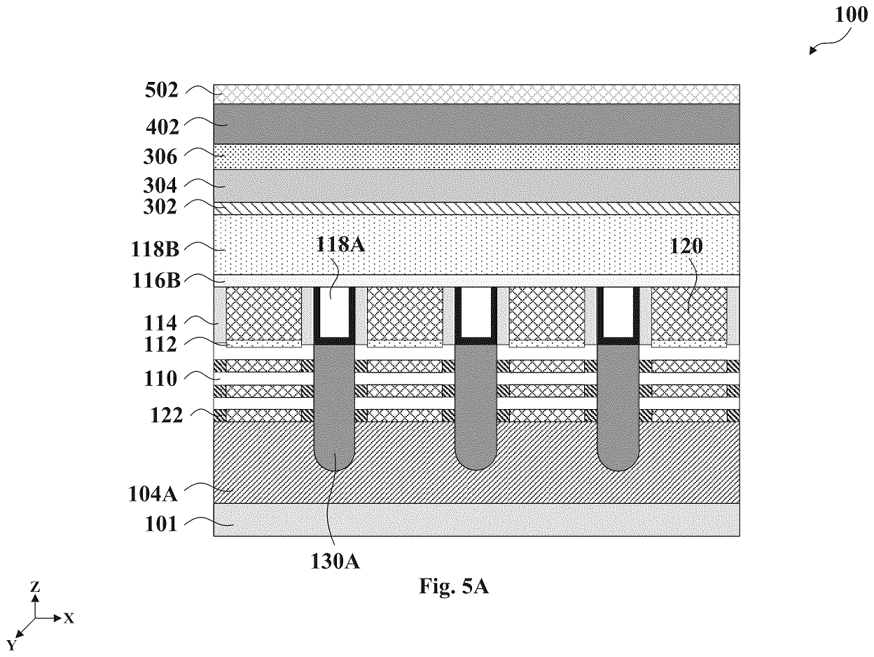

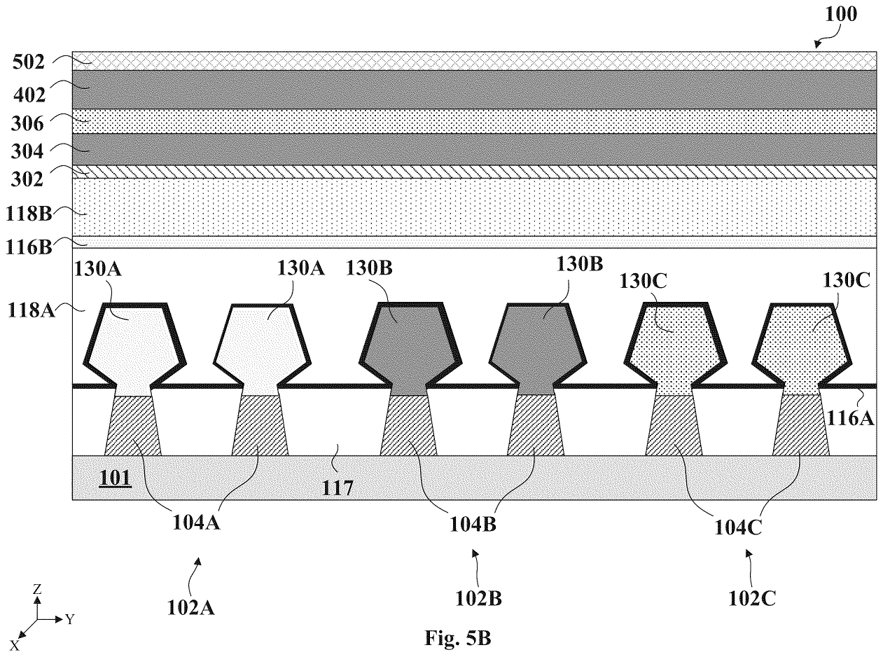

Referring to FIG. 2, in operation 215, a second patterning layer is formed on the first patterning layer. In some embodiments, second patterning layer 502 can be deposited on first patterning layer 402, as shown in FIGS. 5A and 5B. Second patterning layer can be formed of a non-carbon based material. Second patterning layer 502 can be formed of, for example, silicon oxycarbide (SiOC). In some embodiments, SiOC can be deposited by chemical vapor deposition (CVD). In some embodiments, second patterning layer 502 can have a thickness between about 15 nm and about 20 nm. In some embodiments, second patterning layer 502 can include amorphous silicon or silicon oxide with a thickness between about 13 nm and about 20 nm.

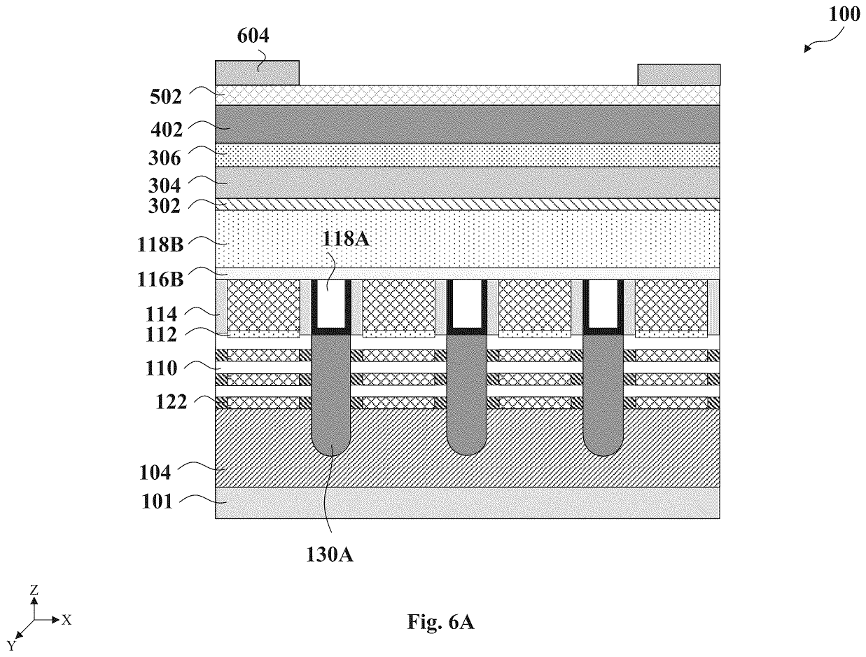

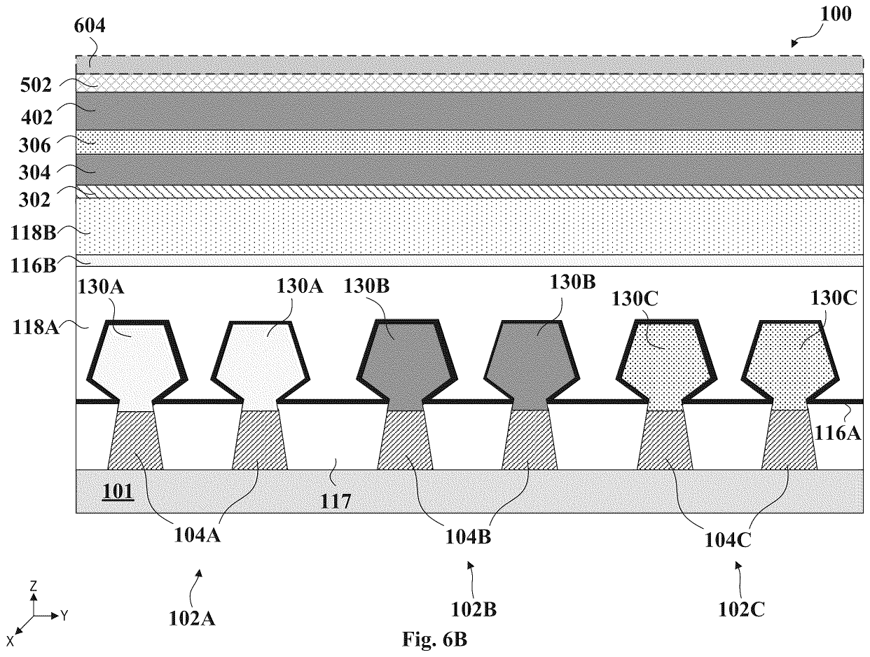

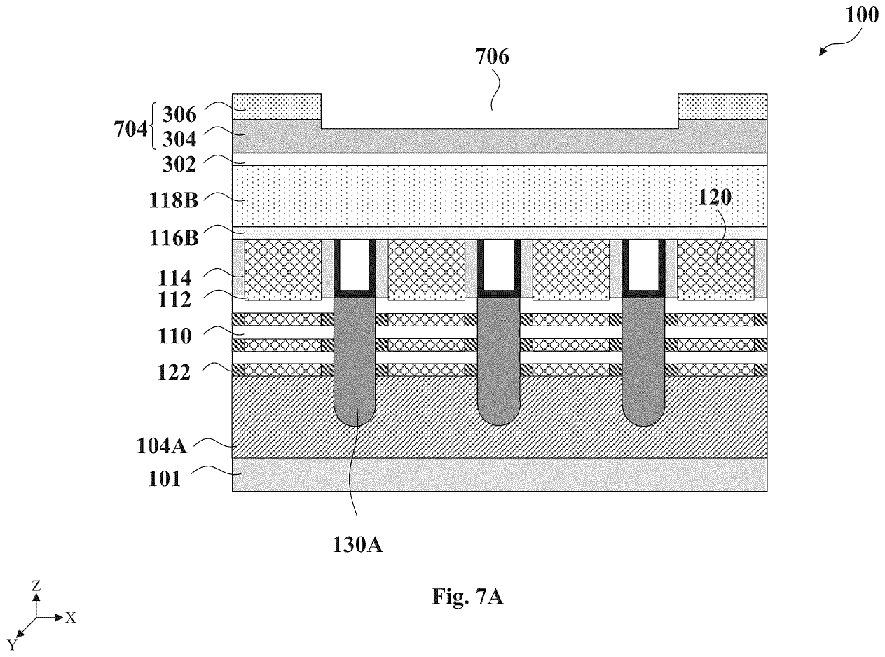

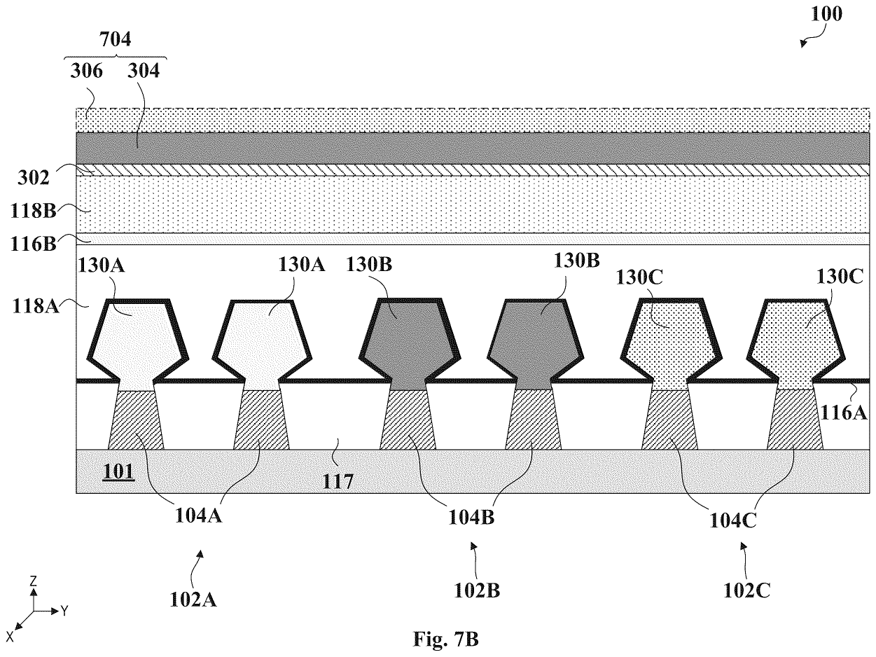

Referring to FIG. 2, in operation 220, a portion of the multi-layer stack structure is etched to form a first patterned mask structure. The first patterned mask structure can include silicon layer 306. The following paragraphs describe the method of forming first patterned mask structure 704 using the operations illustrated in FIGS. 6A, 6B, 7A, and 7B.

According to some embodiments, the process of forming first patterned mask structure 704 can include depositing and patterning a photoresist layer to form first patterned mask 604, where the first patterned mask extends along the y-axis, as shown in FIGS. 6A and 6B. In FIG. 6B, first patterned mask 604 is shown by a dashed line because it is in a plane parallel to the Y-Z plane not passing through line B-B. A process of forming first patterned mask structure 704 can further include (i) etching areas of second patterning layer 502 not protected by first patterned mask 604 to transfer a pattern of first patterned mask 604 to second patterning layer 502, (ii) etching areas of first patterning layer 402 not protected by the etched second patterning layer 502 to transfer the pattern of first patterned mask 604 to first patterning layer 402, (iii) etching areas of silicon layer 306 and a portion of capping layer 304 not protected by the etched first patterning layer 402 to form first patterned mask structure 704. The result of sub-operations (i)-(iii) of operation 220 is shown in FIGS. 7A and 7B. During the above described process of sequentially patterning and etching a portion of the multi-layer stack structure to form first patterned mask structure 704, second patterning layer 502, first patterning layer 402, and silicon layer 306 can be etched using an anisotropic wet etching process or an anisotropic dry etching process.

During sub-operation (i) of operation 220, in some embodiments, second patterning layer 502 can be etched using a carbon tetrafluoride (CF₄) or trifluoromethane (CHF₃) based dry etching process. In some embodiments, H₂ can be co-flowed during the dry etching process. In some embodiments, the dry etching process can be performed using a radio frequency (RF) power of, for example, 750 watts.

In some embodiments, first patterning layer 402 formed of amorphous carbon can be dry etched using at least one of carbonyl sulphide (COS), sulphur dioxide (SO₂), or a combination thereof. The dry etching process can use one or more of oxygen (O₂) and argon (Ar) to remove etch byproducts. In some embodiments, the dry etching process can use a power between about 400 watts and about 600 watts. The dry etching process can use a power of, for example, 500 watts. In some embodiments, the etching can be performed at a temperature between about −150 °C to about 200 °C. In some embodiments, silicon layer 306 can be etched using a tetrafluoromethane (CF₄) based dry etch or a trifluoromethane (CF₃H) based dry etch.

According to some embodiments, first patterned mask structure 704 can include opening 706. After forming first patterned mask structure 704, first patterning layer 402 overlying first patterned mask structure 704 can be removed. In some embodiments, first patterning layer 402 can be removed by a dry etch process using one or more of O₂ and isodiazene (N₂H₂). In some embodiments, second patterning layer 502 can be removed during sub-operations (ii) or (iii) of operation 220 of forming first patterned mask structure 704.

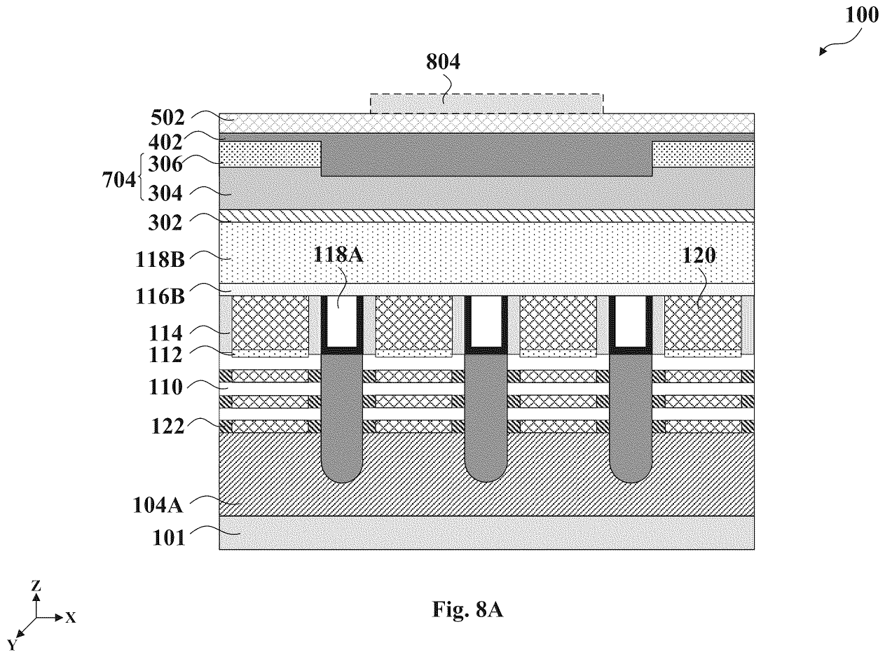

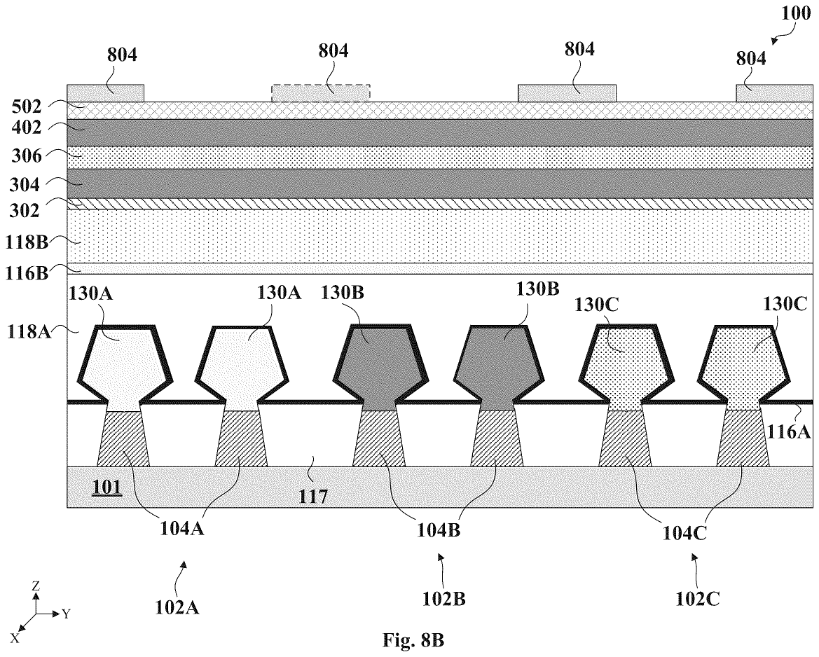

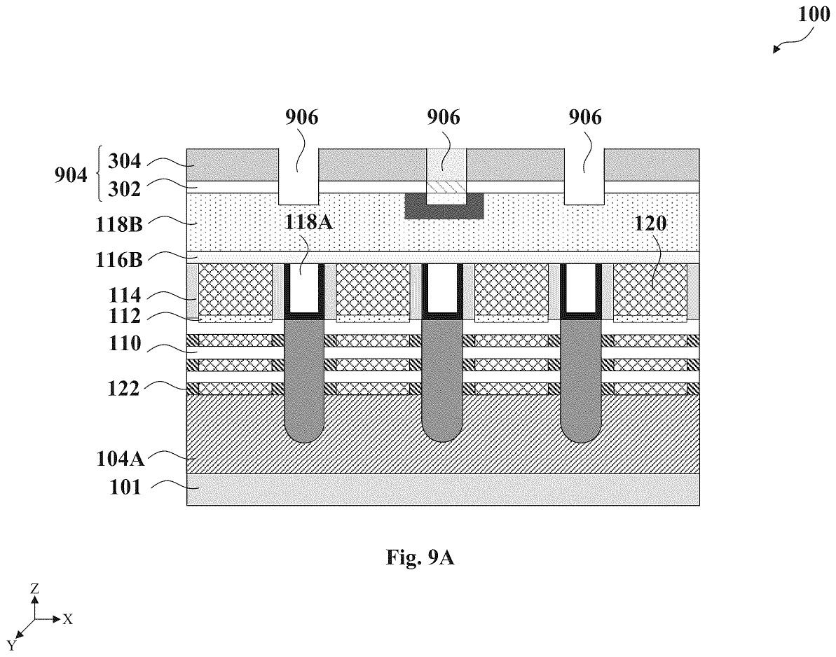

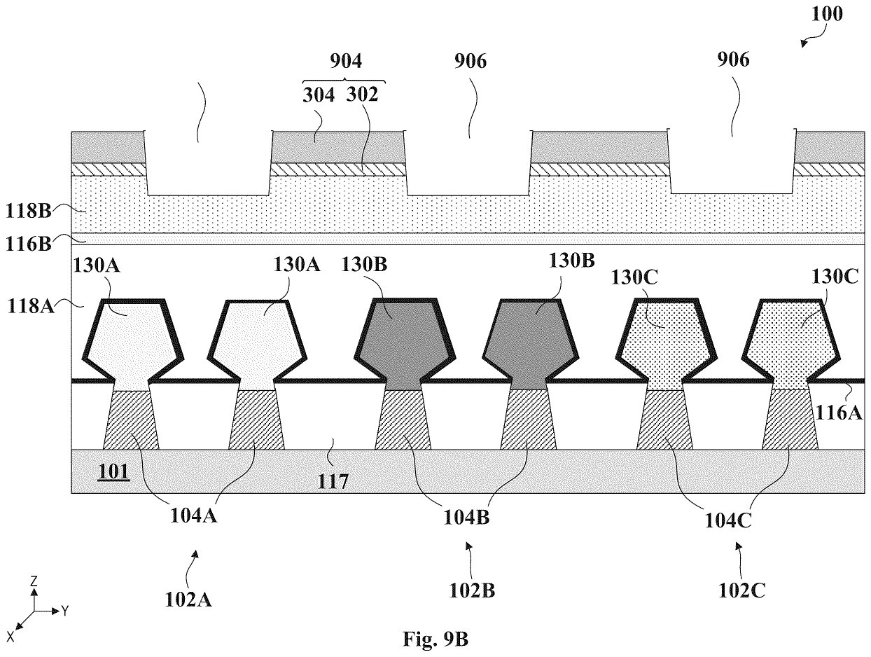

Referring to FIG. 2, in operation 225, the capping layer and the WC layer are patterned and etched to form second patterned mask structure 904. The second patterned mask structure can be formed of capping layer 304 and WC layer 302. The following paragraphs describe a method of forming second patterned mask structure 904. According to some embodiments, second patterned mask structure 904 can be formed using the operations illustrated in FIGS. 8A, 8B, 9A, and 9B.

Forming second patterned mask structure 904 according to some embodiments, can include (i) depositing first patterning layer 402 on first patterned mask structure 704 so that first patterned mask structure 704 can be covered by first patterning layer 402, (ii) depositing second patterning layer 502 on first patterning layer 402, and (iii) depositing and patterning a photoresist layer on second patterning layer 502 to form second patterned mask 804. The results of sub-operations (i)-(iii) of operation 225 are shown in FIGS. 8A and 8B. In FIG. 8B, second patterned mask 804 is shown by a dashed line because it is in a plane parallel to the Y-Z plane not passing through line B-B. According to some embodiments, the method of forming second patterned mask structure 904, can further include (iv) etching second patterning layer 502 and first patterning layer 402, through second patterned mask 804, and (v) etching capping layer 304, WC layer 302 and a portion of second dielectric layer 118B through first patterned mask structure 704 and second patterned mask 804 to form second patterned mask structure 904. The results of operations (iv) and (v) of operation 225 are shown in FIGS. 9A and 9B. After forming second patterned mask structure 904, first patterning layer 402 and second patterning layer 502 can be removed. Second patterned mask structure 904 can be formed of capping layer 304 and WC layer 302. In some embodiments, second patterned mask structure 904 can include openings 906. According to some embodiments, second patterned mask structure 904 can act as a hard mask for forming cut metal drain (CMD) openings in subsequent operations. In some embodiments, first patterned mask structure 704 can be aligned to second patterned mask structure 904 using lithographic alignment. According to some embodiments, second patterned mask structure 904 formed of capping layer 304 and WC layer 302 can have a tapered profile.

In some embodiments, to form second patterned mask structure 904, capping layer 304 can be anisotropically etched using a dry etch process during sub-operation (v) of operation 225. In some embodiments, capping layer 304 that includes silicon oxide, can be etched using a hexafluorobutadiene (C₄F₆) based dry etch process. In some embodiments, O₂ or Ar can be co-flowed with C₄F₆ during the dry etch process. In some embodiments, the dry etching process of capping layer 304 can be performed at an RF power of about 500 watts.

In some embodiments, to form second patterned mask structure 904, WC layer 302 can be anisotropically dry etched, during sub-operation (v) of operation 225. In some embodiments, WC layer 302 can be etched using a nitrogen fluoride (NF₃) and chlorine (Cl₂) based dry etch process. In some embodiments, O₂ can be co-flowed with NF₃ and Cl₂ during the dry etch process. In some embodiments, the dry etching of WC layer 302 can be performed at a power of about 300 watts.

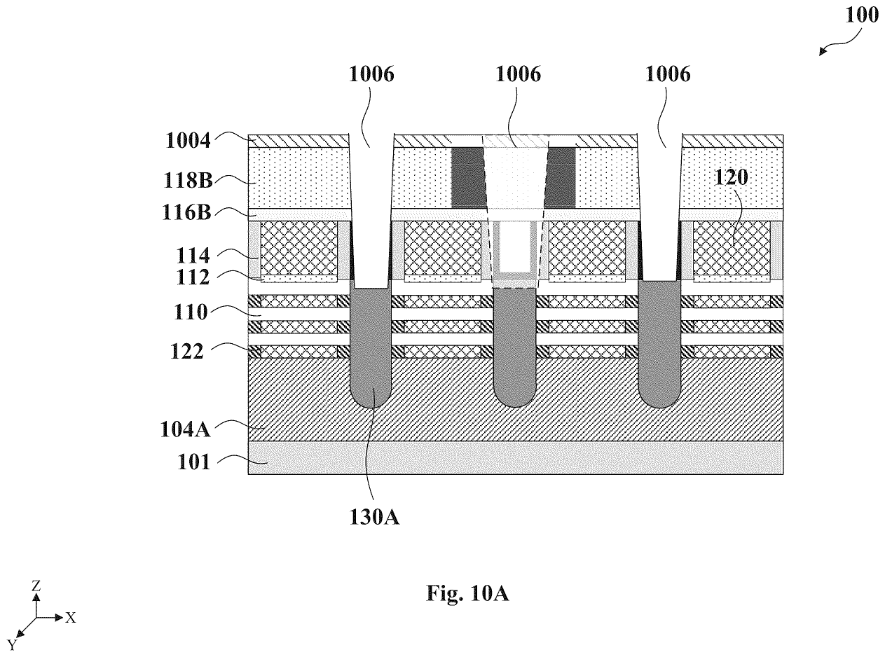

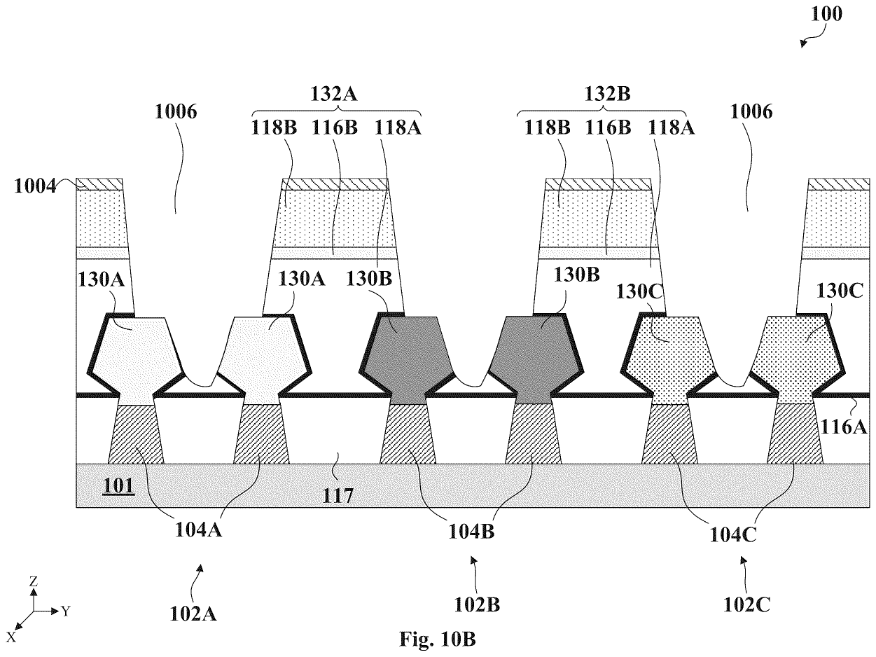

Referring to FIG. 2, in operation 230, the capping layer can be removed from the second patterned mask structure to form patterned mask structure. In some embodiments, after forming second patterned mask structure 904, capping layer 304 can be removed. For example, as shown in FIGS. 10A and 10B, capping layer 304 can be removed from second patterned mask structure 904, to form patterned mask structure 1004. In some embodiments, capping layer 304 formed of silicon dioxide (SiO₂) can be removed using a hexafluoro-1,3-butadiene (C₄F₆) based dry etching process. Patterned mask structure 1004 can act as a hard mask layer for subsequent etching operations. According to some embodiments, patterned mask structure 1004 can be formed of at least one of WC or W, or a combination thereof.

Referring to FIG. 2, in operation 235, the second dielectric layer, the second ESL, the first dielectric layer, and the first ESL are etched through patterned mask structure 1004, to form CMD opening 1006. In some embodiments, as shown in FIGS. 9A and 9B, WC layer 302 can act as the hard mask layer for anisotropically etching second dielectric layer 118B, second ESL 116B, first dielectric layer 118A, and first ESL 116A to form CMD opening 1006. In some embodiments, the anisotropic etch can be a plasma-based dry etch process and can use at least one of tetrafluorocyclobutadiene (C₄F₆) or CF₄. The plasma-based dry etching process can use one or more of carbon monoxide (CO), O₂, Ar, and nitrogen (N₂) to remove etch byproducts. In some embodiments, second dielectric layer 118B, second ESL 116B, first dielectric layer 118A, and first ESL 116A can be etched by a dry etching process using one or more of fluoromethane (CH₃F), difluoromethane (CH₂F₂), and octafluorocyclobutane (C₄F₈). In some embodiments, the plasma-based dry etching process can use an RF power between about 50 watts and about 1000 watts and a radio frequency between about 400 kHz and about 60 MHz. In some embodiments, the plasma-based dry etching process can be performed at a temperature between about −150 °C and about 200 °C. The plasma-based dry etching process is selective to the S/D regions. In other words, the plasma-based dry etching process does not etch S/D regions 130A, 130B, and 130C. In FIG. 10A, one of the CMD openings 1006 is shown by dashed lines because the opening lies in an X-Z plane that does not pass through line B-B but is parallel to an X-Z plane including line B-B.

As shown in FIGS. 10A and 10B, formation of CMD opening 1006 results in formation of isolation structures on either side of CMD opening 1006. As shown in FIG. 10B, isolation structures 132A and 132B can be formed of second dielectric layer 118B, second ESL 116B, and first dielectric layer 118A. In some embodiments, isolation structures 132A and 132B can have a tapered profile, as shown in FIG. 10B. After forming CMD opening 1006, WC layer 302 can be removed. In some embodiments, a wet etching process using diluted hydrogen peroxide (dH₂O₂) with H₂O₂ and H₂O in the ratio between about 1:20 and about 1:5 can be used to remove WC layer 302. In some embodiments, the wet etching can be performed at temperature of about 67 °C. In some embodiments, WC layer can be wet etched using hydrochloric acid (HCl), H₂O₂, and H₂O.

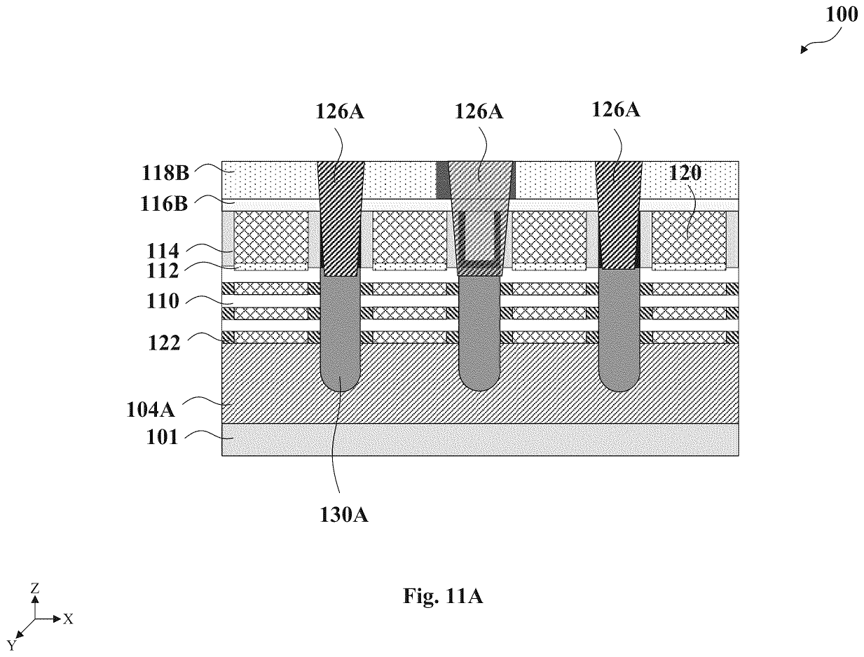

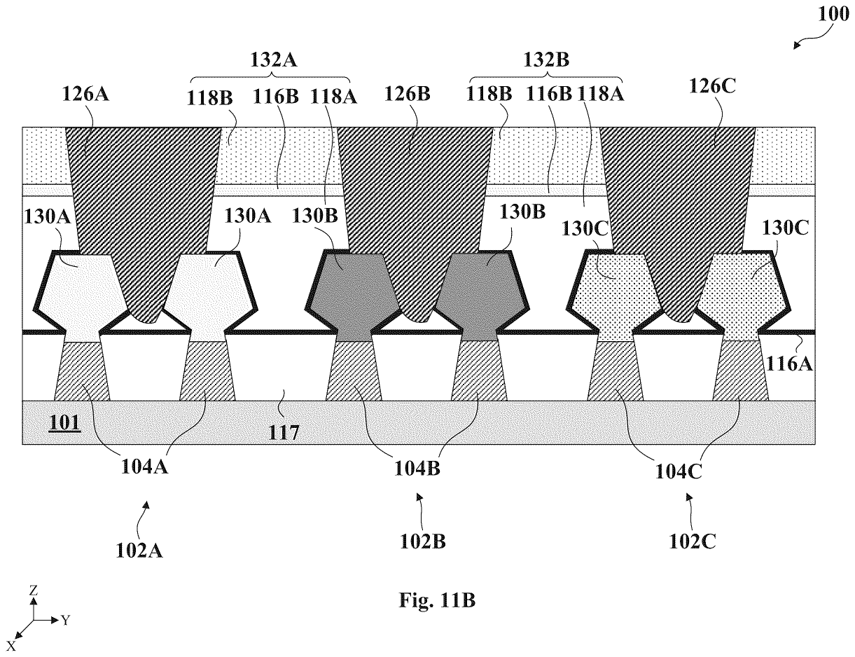

Referring to FIG. 2, in operation 240, S/D contact structures are formed within the CMD openings. For example, as described with reference to FIGS. 11A and 11B, S/D contact structures 126A, 126B, and 126C are formed on S/D regions 130A, 130B, and 130C respectively. Subsequently, top surfaces of S/D contact structure 126A, 126B, and 126C are substantially co-planarized with a top surface of the second dielectric layer 118B. The formation of S/D contact structures 126A, 126B, and 126C can include sequential operations of (i) forming a silicide layer (not shown) within CMD openings 1006, (ii) depositing a liner layer within CMD opening 1006 (not shown), (iii) depositing a metal layer on the silicide layer and liner layer to fill CMD opening 1006 to form S/D contact structures 126A, 126B, and 126C, and (iv) performing a chemical mechanical polishing (CMP) process to substantially coplanarize top surfaces of S/D contact structures 126A, 126B, and 126C with a top surface of second dielectric layer 118B, to form the structures shown in FIGS. 11A and 11B. Isolation structure 132A can isolate S/D contact structure 126A from S/D contact structure 126B. Isolation structure 132B can isolate S/D contact structure 126B from S/D contact structure 126C.

The present disclosure provides a method (e.g., method 200) of depositing first patterning layer 402 with a high Young's modulus. First patterning layer 402 disclosed herein, owing to its high Young's modulus, can (a) withstand the stress of multiple etching cycles without undergoing degradation, (b) reduce line bending (form a masking layer with substantially vertical sidewalls) issues during patterning and etching operations to maintain positional and dimensional accuracy of device features, and (c) provide etch selectivity for effectively protecting underlying layers during etching operations. The disclosed method of forming first patterning layer 402 can also help deposit a non-conformal patterning layer within openings and/or trenches formed during formation of the isolation structures. The non-conformal layer is evenly deposited over flat surface areas as well as areas with deep features (e.g., deep trenches and narrow openings). First patterning layer 402 has a substantially planarized top surface irrespective of the features on an underlying layer.

In some embodiments, a method can include providing a field effect transistor (FET) comprising a first dielectric layer, depositing a multi-layer stack structure on the first dielectric layer, depositing a carbon-based patterning layer on the multi-layer stack structure, and depositing a patterning layer on the carbon-based patterning layer. In some embodiments, the method further includes etching the carbon-based patterning layer and the patterning layer to form a patterned mask structure, wherein the patterned mask structure comprises a tungsten-carbide (WC) layer, etching a portion of the multi-layer stack structure and the first dielectric layer through the patterned mask structure to form a trench, and filling the trench with a metal layer.

In some embodiments, a method can include providing a substrate with a field effect transistor (FET), depositing a multi-layer stack structure on the FET, depositing an amorphous-carbon (a-C) layer on the multi-layer stack structure, forming a patterning layer on the a-C layer, etching the a-C layer and the patterning layer to form a patterned mask, etching a first plurality of layers of the multi-layer stack structure through the patterned mask to form a patterned mask structure, etching a second plurality of layers of the multi-layer stack structure to form a contact opening, and forming a contact structure within the contact opening.

In some embodiments, a structure can include a first field effect transistor (FET) comprising a first channel region and a first source/drain (S/D) region, a second FET comprising a second channel region and a second S/D region, and a third FET comprising a third channel region and a third source/drain region. In some embodiments, the structure further includes a first isolation structure disposed between a first contact structure of the first S/D region and a second contact structure of the second S/D region, wherein a top portion of the first isolation structure has a first width, and a second isolation structure disposed between the second contact structure of the second S/D region and a third contact structure of the third S/D region, wherein a top portion of the second isolation structure has a second width, and wherein a ratio of the first width to the second width is between A and B.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a field effect transistor (FET) comprising a first dielectric layer;
depositing a multi-layer stack structure on the first dielectric layer;
depositing a carbon-based patterning layer on the multi-layer stack structure;
depositing a patterning layer on the carbon-based patterning layer;
etching the carbon-based patterning layer and the patterning layer to form a patterned mask structure, wherein the patterned mask structure comprises a hard mask layer;
etching a portion of the multi-layer stack structure and the first dielectric layer through the patterned mask structure to form a trench; and
filling the trench with a metal layer.

2. The method of claim 1, wherein forming the multi-layer stack structure comprises:
depositing a second etch stop layer on the first dielectric layer;
forming a second dielectric layer on the second etch stop layer;
depositing the hard mask layer on the second dielectric layer;
depositing an oxide layer on the hard mask layer; and
forming a silicon layer on the oxide layer.

3. The method of claim 1, further comprising depositing the carbon-based patterning layer by a plasma enhanced chemical vapor deposition (PECVD) process.

4. The method of claim 3, wherein the PECVD process is performed at a pressure between about 1 torr and about 8 torr and at a power between about 800 watts and about 4000 watts to form the carbon-based first patterning layer with a Young's modulus between about 80 giga pascals (GPa) and about 120 GPa.

5. The method of claim 1, wherein etching the carbon-based patterning layer comprises dry etching using a plasma comprising oxygen and sulphur dioxide.

6. The method of claim 1, wherein etching the patterning layer comprises dry etching using a plasma comprising tetrafluoromethane (CF₄) and trifluoromethane (CHF₃).

7. The method of claim 1, further comprising depositing the carbon-based patterning layer with a thickness between about 40 nm and about 53 nm.

8. The method of claim 1, further comprising etching the carbon-based patterning layer using a sulphide-based dry etching process.

9. A method, comprising:
providing a substrate with a field effect transistor (FET);
depositing a multi-layer stack structure on the FET;
depositing an amorphous-carbon (a-C) layer on the multi-layer stack structure;
forming a patterning layer on the a-C layer;
etching the a-C layer and the patterning layer to form a patterned mask;
etching a first plurality of layers of the multi-layer stack structure through the patterned mask to form a patterned mask structure;
etching a second plurality of layers of the multi-layer stack structure to form a contact opening; and
forming a contact structure within the contact opening.

10. The method of claim 9, wherein depositing the a-C layer comprises flowing a processing gas over the substrate, the processing gas comprising acetylene (C₂H₂) and hydrogen.

11. The method of claim 9, further comprising depositing the a-C layer at a temperature between about 350 °C and about 450 °C.

12. The method of claim 9, wherein etching the first plurality of layers comprises etching a silicon layer and a portion of a capping layer of the multi-layer stack structure.

13. The method of claim 9, further comprising depositing the a-C layer at a pressure between about 9 torr and about 18 torr to form the a-C layer with a Young's modulus between about 20 GPa and about 80 GPa.

14. The method of claim 9, further comprising depositing the a-C layer at a pressure between about 1 torr and about 9 torr to form the a-C layer with a Young's modulus between about 80 GPa and about 120 GPa.

15. The method of claim 9, further comprising:
depositing the a-C layer at a pressure between about 1 torr and about 9 torr; and
applying a low power frequency with power between about 800 watts and about 4000 watts to form the a-C layer with a Young's modulus between about 80 GPa and about 120 GPa.

16. The method of claim 9, further comprising depositing the a-C layer by applying a low power frequency with a power of about 0 watts.

17. The method of claim 9, further comprising depositing the a-C layer conformally on a top surface of the substrate, wherein the top surface of the substrate comprises a plurality of structures, and wherein a top surface of the a-C layer deposited on the plurality of structures is substantially coplanar with a top surface of the a-C layer deposited between the plurality of structures.

18. A method, comprising:
providing a substrate with a field effect transistor (FET);
depositing a multi-layer stack structure on the FET;
depositing an amorphous-carbon (a-C) layer on the multi-layer stack structure, wherein the a-C layer has a substantially planar surface;
etching the a-C layer to form a patterned mask;
etching a first plurality of layers of the multi-layer stack structure through the patterned mask to form a contact opening; and
forming a contact structure within the contact opening.

19. The method of claim 18, further comprising depositing the a-C layer comprises performing a chemical vapor deposition process.

20. The method of claim 18, wherein depositing the (a-C) layer on the multi-layer stack structure comprises depositing the a-C layer within trenches surrounded by a second plurality of layers of the multi-layer stack structure, wherein a portion of the a-C layer formed on a top surface of the second plurality of layers of the multi-layer stack structure is substantially coplanar with a top surface of another portion of the a-C layer formed within the trenches.
